(19) United States
(12) Patent Application Publication
(10) Pub. No.: US 2025/0201493 A1
(43) Pub. Date: Jun. 19, 2025

(54) CAPACITOR

(71) Applicant: Murata Manufacturing Co., Ltd., Nagaokakyo-shi (JP)

(72) Inventors: Sota YANAI, Nagaokakyo-shi (JP); Yasuhiro SHIMIZU, Nagaokakyo-shi (JP); Masaki NAGATA, Nagaokakyo-shi (JP); Nobuaki SHIRAI, Nagaokakyo-shi (JP)

(21) Appl. No.: 19/068,170

(22) Filed: Mar. 3, 2025

Related U.S. Application Data
(63) Continuation of application No. PCT/JP2023/026071, filed on Jul. 14, 2023.

(30) Foreign Application Priority Data
Nov. 1, 2022 (JP) 2022-175701

(51) Int. Cl. H01G 11/40; H01G 11/24; H01G 11/36

(52) U.S. Cl. CPC H01G 11/40; H01G 11/24; H01G 11/36

(57) ABSTRACT

A capacitor that includes: a substrate; fiber-shaped conductive members on the substrate; a dielectric layer covering the fiber-shaped conductive members; and a conductor layer covering the dielectric layer, wherein the fiber-shaped conductive members, the dielectric layer, the conductor layer, a space among the fiber-shaped conductive members, and the conductor layer constitute a composite bulk member, in one section in the thickness direction of the substrate: each of the fiber-shaped conductive member has a maximum height Hₘₐₓ, the composite bulk member has outer peripheral regions that each occupy a region up to twice the maximum height Hₘₐₓ from an outer edge of the composite bulk member, and a central region between the outer peripheral regions, and at least one of the outer peripheral regions includes a part where a first total area occupancy proportion is higher than a second total area occupancy proportion in the central region.

### CROSS REFERENCE TO RELATED APPLICATIONS

The present application is a continuation of International application No. PCT/JP2023/026071, filed Jul. 14, 2023, which claims priority to Japanese Patent Application No. 2022-175701, filed Nov. 1, 2022, the entire contents of each of which are incorporated herein by reference.

### TECHNICAL FIELD

The present disclosure relates to a capacitor and, more particularly, to a capacitor that has a conductor-dielectric-conductor structure.

### BACKGROUND ART

Conventionally, it is known that capacitors can be manufactured with the use of a fiber-shaped members. For example, Patent Document 1 describes a method of forming a capacitor that has a metal-insulator-metal (MIM) structure by forming fiber-shaped members on a substrate (base surface) and sequentially forming, on the surface thereof, a lower plate (metal), an insulating layer, and an upper plate (metal).

Patent Document 1: Japanese Patent Application Laid-Open (Translation of PCT Application) No. 2010-506391

Non-Patent Document 1: Michael F L De Volder, Sei Jin Park, Sameh H Tawfick, Daniel O Vidaud and A John Hart, “Fabrication and electrical integration of robust carbon nanotube micropillars by self-directed elastocapillary densification”, Journal of Micromechanics and Microengineering, 2011.

### SUMMARY OF THE DISCLOSURE

When the fiber-shaped members have conductivity, a capacitor that has a conductor-dielectric-conductor structure can be formed by forming, on the surfaces of the fiber-shaped conductive members, a dielectric layer and further forming a conductor layer.

As a plurality of fiber-shaped conductive members, for example, vertically aligned carbon nanotubes (hereinafter, referred to also as “VACNTs”) can be used. VACNTs can be obtained by high-density growth thereof on a substrate with a catalyst attached thereto. Typically, multiple adjacent VACNTs are entangled with each other and integrated to form a forest.

Although the multiple VACNTs integrated are covered with a dielectric layer and a conductor layer to constitute a composite bulk member, the mechanical strength thereof may be insufficient. If the composite bulk member is damaged in use of the capacitor, the performance of the capacitor will be decreased.

An object of the present disclosure is to provide a

capacitor including a composite bulk member, which is excellent in mechanical strength.

According to a gist of the present disclosure, provided is a capacitor including: a substrate with conductivity; a plurality of fiber-shaped conductive members on the substrate and electrically connected to the substrate; a dielectric layer covering the surface of the fiber-shaped conductive members; and a conductor layer covering the surface of the dielectric layer, wherein the plurality of fiber-shaped conductive members, the dielectric layer, the conductor layer, a space among the plurality of fiber-shaped conductive members covered with the dielectric layer, and the conductor layer constitute a composite bulk member, in a first section of the capacitor in the thickness direction of the substrate: each of the fiber-shaped conductive members has a maximum height Hₘₐₓ, the composite bulk member has a first outer peripheral region on a first side and a second outer peripheral region on a second side, each of the first outer peripheral region and the second outer peripheral region occupying a region up to twice the maximum height Hₘₐₓ from an outer edge of the composite bulk member, and a central region between the first outer peripheral region on the first side and the second outer peripheral region on the second side, and at least one of the first outer peripheral region and the second outer peripheral region includes a part where a first total area occupancy proportion of the fiber-shaped conductive members and the dielectric layer is higher than a second total area occupancy proportion of the fiber-shaped conductive members and the dielectric layer in the central region.

According to a gist of the present disclosure, provided is a capacitor including: a substrate with conductivity; a plurality of fiber-shaped conductive members on the substrate and electrically connected to the substrate; a dielectric layer covering the surface of the fiber-shaped conductive members; and a conductor layer covering the surface of the dielectric layer, wherein the plurality of fiber-shaped conductive members, the dielectric layer, the conductor layer, a space among the plurality of fiber-shaped conductive members covered with the dielectric layer, and the conductor layer constitute a composite bulk member, in a first section of the capacitor in the thickness direction of the substrate: the fiber-shaped conductive member has a maximum height Hₘₐₓ, the composite bulk member has a first outer peripheral region on a first side and a second outer peripheral region on a second side, each of the first outer peripheral region and the second outer peripheral region occupying a region up to twice the maximum height Hₘₐₓ from an outer edge of the composite bulk member, and a central region between the first outer peripheral region on the first side and the second outer peripheral region on the second side, and at least one of the first outer peripheral region and the second outer peripheral region includes a part where a first total area occupancy proportion of the fiber-shaped conductive members, the dielectric layer, and the conductor layer is higher than a second total area occupancy proportion of the fiber-shaped conductive members, the dielectric layer, and the conductor layer in the central region.

According to a gist of the present disclosure, provided is a capacitor including: a substrate with conductivity; a plurality of fiber-shaped conductive members on the substrate and electrically connected to the substrate; a dielectric layer covering the surface of the fiber-shaped conductive members; and a conductor layer covering the surface of the dielectric layer, wherein the plurality of fiber-shaped conductive members, the dielectric layer, the conductor layer, a space among the plurality of fiber-shaped conductive members covered with the dielectric layer, and the conductor layer constitute a composite bulk member, in a first section of the capacitor in the thickness direction of the substrate the fiber-shaped conductive member has a maximum height Hₘₐₓ, and in a second section of the capacitor in parallel with an in-plane direction of the substrate, the composite bulk member has an outer peripheral region that occupies a region up to twice the maximum height Hₘₐₓ from an outer edge of the composite bulk member, and a central region surrounded by the outer peripheral region, and the outer peripheral region includes a part where a first total area occupancy proportion of the fiber-shaped conductive members, the dielectric layer, and the conductor layer is higher than a second total area occupancy proportion of the fiber-shaped conductive members, the dielectric layer, and the conductor layer in the central region.

According to the present disclosure, provided is a capacitor including a composite bulk member, which is excellent in mechanical strength.

### BRIEF EXPLANATION OF THE DRAWINGS

FIG. 1 is a schematic sectional view of capacitors according to Embodiments 1 and 2 of the present disclosure.

FIG. 2 is an enlarged view of a part A in FIG. 1.

FIG. 3 is a schematic sectional view of FIG. 1 in an in-plane direction of a substrate.

FIG. 4 is a schematic sectional view of capacitors according to Modification Example 1 of Embodiment 1 of and Modification Example 2 of Embodiment 2 of the present disclosure.

FIG. 5 is an enlarged view of a part B in FIG. 4.

FIG. 6 is a schematic sectional view of a capacitor according to Embodiment 3 of the present disclosure.

FIG. 7 is an enlarged view of a part D in FIG. 6.

FIG. 8 is a schematic sectional view of a capacitor according to Modification Example 3 of Embodiment 3 of the present disclosure.

FIG. 9 is an electron microscope image obtained by photographing, from a side surface, a forest including inclined CNTs and a part of a substrate, obtained in Manufacturing Example 1.

FIG. 10A is an SEM image obtained by photographing a part of an outer peripheral region in a polished XZ section of a composite bulk member obtained according to Manufacturing Example1.

FIG. 10B is an SEM image obtained by photographing a part of a central region in the polished XZ section of the composite bulk member obtained according to Manufacturing Example 1.

FIG. 11A is an SEM image obtained by photographing a part of the outer peripheral region in a polished XY section of the composite bulk member obtained according to Manufacturing Example 1.

FIG. 11B is an SEM image obtained by photographing a part of the central region in the polished XY section of the composite bulk member obtained according to Manufacturing Example 1.

### DETAILED DESCRIPTION OF THE PREFERRED EMBODIMENTS

Hereinafter, a capacitor according to an aspect of the present disclosure will be described in detail with reference to illustrated embodiments. It is to be noted that the drawings include some schematic drawings, and do not reflect actual dimensions or ratios in some cases. The present disclosure is not limited to these embodiments.

### Embodiment 1

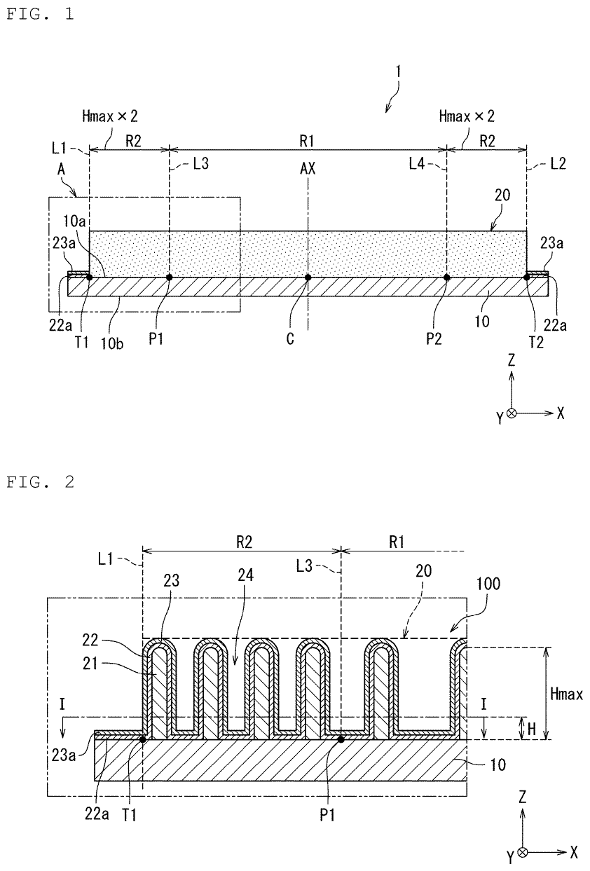

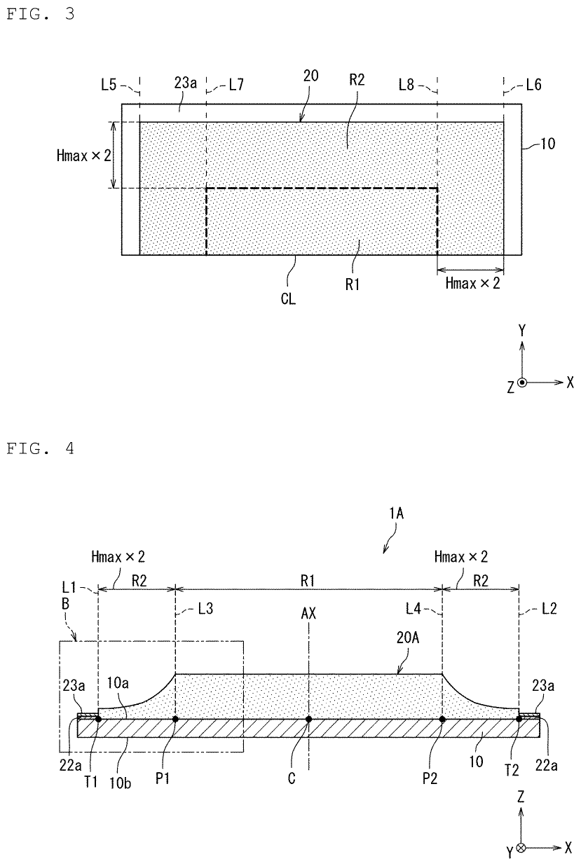

FIG. 1 is a schematic sectional view of a capacitor according to Embodiment 1. FIG. 1 shows a section in the thickness direction of a substrate 10. FIG. 1 shows therein, for the sake of convenience, the substrate 10 and the outer shape of a composite bulk member 20, while fiber-shaped conductive members 21, a dielectric layer 22, a conductor layer 23, and a space 24 are omitted. FIG. 2 is an enlarged view of a part A in FIG. 1. FIG. 2 schematically shows therein the fiber-shaped conductive members 21 sequentially covered with the dielectric layer 22 and the conductor layer 23. For the sake of convenience, FIG. 2 shows only parts of the substrate 10, fiber-shaped conductive members 21, dielectric layer 22, and conductor layer 23. FIG. 3 is a schematic sectional view of FIG. 1 in an in-plane direction of the substrate.

In the drawings, the thickness direction of the substrate 10 is defined as a Z direction. The straight line including the center C of the substrate 10 when the capacitor 1 is viewed from the Z direction and extending along the Z direction is defined as a central axis AX. The center C of the substrate 10 is typically coaxial with the center of the capacitor 1. A direction that is orthogonal to the Z direction of a section obtained by cutting the capacitor 1 along a plane including the central axis AX and extending in the Z direction is defined as an X direction (referred to also as a width direction in an XZ section). The X direction is an example of a direction in parallel with the in-plane direction of the substrate 10. A direction that is orthogonal to the Z direction and the X direction is defined as a Y direction (referred to also as a width direction in a YZ section).

The plane obtained by cutting the capacitor 1 along a plane that is formed by a straight line extending in the X direction and a straight line extending in the Z direction and includes the central axis AX is defined as an XZ section.

The XZ section is an example of a section in the thickness direction of the substrate 10. The plane obtained by cutting the capacitor 1 along a plane that is formed by a straight line extending in the Y direction and a straight line extending in the Z direction and includes the central axis AX is defined as a YZ section. The YZ section is another example of the section in the thickness direction of the substrate 10. The plane obtained by cutting the capacitor 1 along a plane that is formed by a straight line extending in the X direction and a straight line extending in the Y direction is defined as an XY section. The XY section is a section in parallel with the in-plane direction of the substrate 10. The center C of the substrate 10 is the center of the smallest circle enclosing the substrate 10 when the capacitor 1 is viewed from the Z direction.

In the XZ section, the X direction may be referred to as a left-right direction. The right side of an element refers to the side of the element in the rightward direction. The left side of an element refers to the side of the element in the leftward direction.

### (Configuration)

The capacitor 1 includes: a substrate 10 with conductivity; a plurality of fiber-shaped conductive members 21 disposed on the substrate 10 and electrically connected to the substrate 10; a dielectric layer 22 that covers the surface of the fiber-shaped conductive members 21; and a conductor layer 23 that covers the surface of the dielectric layer 22. The capacitor 1 may have a conductive member (not shown) in contact with the conductor layer 23. The plurality of fiber-shaped conductive members 21, the dielectric layer 22, the conductor layer 23, and the space 24 formed among the plurality of fiber-shaped conductive members covered with the dielectric layer 22 and the conductor layer 23 constitute the composite bulk member 20. The space 24 may be filled with a filling material such as resin. The conductive member will be described later.

In the capacitor 1, the term “on the substrate 10” can be rephrased as a face (surface 10a to be described later) that is an outer surface of the substrate 10, in parallel with a plane (XY plane) formed by a straight line extending in the X direction and a straight line extending in the Y direction.

In addition to the surface (provided that the regions directly joined to the substrate 10 are excluded) of the fiber-shaped conductive members 21, the dielectric layer 22 may cover a part of the surface 10a of the substrate 10 without any fiber-shaped conductive member 21 disposed thereon among the plurality of fiber-shaped conductive members 21. The dielectric layer 22 may be formed to be continuous with a dielectric part 22a that covers a part of the surface 10a of the substrate 10 without any fiber-shaped conductive member 21 disposed thereon, outside the plurality of fiber-shaped conductive members 21. The composite bulk member 20 includes, however, no dielectric part 22a.

The conductor layer 23 may cover the dielectric layer 22 among the plurality of fiber-shaped conductive members 21, in addition to the dielectric layer 22 covering the surface of the fiber-shaped conductive members 21. A part of the conductor layer 23, covering the dielectric layer 22 among the plurality of fiber-shaped conductive members 21, can be understood as defining the bottom of the space 24 (for example, the bottom of the trench). The conductor layer 23 may be formed to be continuous with a conductor part 23a that covers the dielectric part 22a outside the plurality of fiber-shaped conductive members 21. The composite bulk member 20 includes, however, no conductor part 23a.

The fiber-shaped conductive members 21 are directly joined to the substrate 10. More specifically, the fiber-shaped conductive members 21 and the substrate 10 are joined in direct contact with each other. The fiber-shaped conductive members 21 are directly synthesized on the surface 10a of the substrate 10.

The plurality of fiber-shaped conductive members 21 have conductivity, (which are typically conductors), which can be kept at the same potential or voltage as each other with the members electrically connected to the substrate 10. Accordingly, a conductor-dielectric-conductor structure is formed by the fiber-shaped conductive members 21, the dielectric layer 22, and the conductor layer 23. Such a conductor-dielectric-conductor structure can be understood as corresponding to a so-called MIM structure (metal-insulator-metal structure). The capacitor 1 that has such a structure can achieve a high capacitance density from the large specific surface area of the fiber-shaped conductive members 21.

In a section in the thickness direction (XZ section herein), the fiber-shaped conductive member 21 has a maximum height Hₘₐₓ. The composite bulk member 20 has, in the section in the thickness direction, outer peripheral regions R2 on one side and the other side that each occupy a region up to twice the maximum height Hₘₐₓ in the direction from the outer edge of the composite bulk member 20 toward the central axis AX, and a central region R1 sandwiched between the outer peripheral regions R2 on one side and the other side.

Hereinafter, the XZ section will be mainly described as an example of the section in the thickness direction.

As shown in FIG. 2, in the section in the thickness direction, the fiber-shaped conductive members 21 in the outer peripheral region R2 is more densely packed than those in the central region R1. Thus, the outer peripheral region R2 includes a part where the total area occupancy proportion S₂₁ of the fiber-shaped conductive members 21 and the dielectric layer 22 is higher than the total area occupancy proportion S₁₁ of the fiber-shaped conductive members 21 and the dielectric layer 22 in the central region R1.

The fact that the outer peripheral region R2 “includes a part where the area occupancy proportion S₂₁ is higher” refers to the fact that the area occupancy proportion S₂₁ in at least a part of the outer peripheral region R2 in any one section in the thickness direction is higher than the area occupancy proportion S₂₁ in a part of the central region R1 in the same section in the thickness direction. The fact is not intended to mean that the area occupancy proportion S₂₁ needs to be higher than the area occupancy proportion S₁₁ in the whole section in the thickness direction.

The fact that “the area occupancy proportion S₂₁ is higher than the area occupancy proportion Su” can be paraphrased as the fact that “the space 24 present in outer peripheral region R2 is narrower than space 24 present in central region R1”. As compared with a composite bulk member that has a uniform area occupancy proportion, the composite bulk member 20 according to the present embodiment has higher mechanical strength in the outer peripheral regions R2. The fact that “the area occupancy proportion S₂₁ is higher than the area occupancy proportion Su” can also be paraphrased as the fact that “the average number density N₂ of the fiber-shaped conductive members 21 present in the outer peripheral region R2 is higher than the average number density N₁ of the fiber-shaped conductive members 21 present in the central region R1”.

When the space is reduced, the large specific surface area of the fiber-shaped conductive members 21 will be lost, and as a result, the performance of the capacitor 1 may be degraded, for example, the volume capacitance density of the capacitor 1 may be decreased. In the present embodiment, increasing the area occupancy proportion S₂₁ in only the outer peripheral region R2 allows the mechanical strength of the composite bulk member 20 to be improved while keeping the performance of the capacitor 1 from being degraded.

The fact that “the area occupancy proportion S₂₁ is higher” means that the difference between the area occupancy proportions S₁₁ and S₂₁ is 5% or more. More specifically, the fact refers to S₂₁/S₁₁≥1.05. S₂₁/S₁₁ may be 1.2 or more, 2 or more, or 5 or more.

### (Composite Bulk Member)

The composite bulk member 20 includes the plurality of fiber-shaped conductive members 21 (hereinafter, referred to as conductive fibers 21), the dielectric layer 22, the conductor layer 23, and the space 24 formed among the plurality of conductive fibers 21 (hereinafter, simply referred to also as covered conductive fibers 21) covered with the dielectric layer 22 and the conductor layer 23.

### Method for Determining Composite Bulk Member 20

The composite bulk member 20 can be determined from a section (for example, a XZ section) in the thickness direction of the capacitor 1. The composite bulk member 20 is, because including no dielectric part 22a or conductor part 23a as mentioned above, determined to exclude the parts.

First, the space 24 formed among the covered conductive fibers 21 is embedded with any appropriate filling resin. Next, the center C of the substrate 10 is determined with the capacitor 1 viewed from the Z direction.

The section (XZ section herein) including the center C in the thickness direction of the capacitor 1 is exposed by polishing. The obtained XZ section (No. 1) is observed with a scanning electron microscope (SEM). The substrate 10; and a first member (not shown) including the conductive fibers 21, the dielectric layer 22 (and the dielectric part 22a, if present, the same shall apply hereinafter) the conductor layer 23 (and the conductor part 23a, if present, the same shall apply hereinafter), and the filling resin (corresponding to the space 24 mentioned above), disposed on the front surface 10a of the substrate 10, can be confirmed in the SEM image of the XZ section (No. 1). Furthermore, a conductive member can be present.

The SEM image is subjected to image processing to identify and distinguish from each other the conductive fibers 21, the dielectric layer 22, the conductor layer 23, the filling resin (space 24), and furthermore, the conductive member in the first member. Elemental analysis by energy dispersive X-ray spectroscopy (EDX) may be used in combination for the identification.

In the XZ section, the composite bulk member 20 is substantially quadrangular. The conductive fibers 21 in the vicinity of the four corners of the composite bulk member 20 are each identified in the SEM image. In this identification, a part including each of the corners in the SEM image may be enlarged so as to obtain an observation field of view of about 1 μm×1 μm.

The leftmost conductive fiber 21 located on the leftmost side of the first member closest to the substrate 10 is identified in the SEM image. Then, the dielectric layer 22 and conductor layer 23 covering the leftmost conductive fiber 21 are determined. These layers can be present to be respectively continuous with the dielectric part 22a and the conductor part 23a. The thickness of the dielectric layer 22 (and the dielectric part 22a, the same shall apply hereinafter) covering the conductive fiber 21 is substantially uniform in terms of manufacturing method. Thus, the outer edge of the dielectric layer 22 covering the leftmost conductive fiber 21 can be determined in consideration of the thickness of the dielectric layer 22 covering the other conductive fibers 21. The thickness of the conductor layer 23 (and the conductor part 23a, the same shall apply hereinafter) covering the conductive fiber 21 with the dielectric layer 22 interposed therebetween is also substantially uniform in terms of manufacturing method. Thus, the outer edge of the conductor layer 23 covering the leftmost conductive fiber 21 can be determined in consideration of the thickness of the conductor layer 23 covering the other conductive fibers 21.

Drawn is a first straight line L1 in contact with the determined outer edge of the conductor layer 23 and in parallel with the central axis AX. The first straight line L1 is intended to define the boundary (virtual boundary, the same shall apply hereinafter) between the dielectric layer 22 and the dielectric part 22a and the boundary between the conductor layer 23 and the conductor part 23a. With respect to the first straight line L1, the dielectric layer 22 is located on the right side, and the dielectric part 22a is located on the left side. With respect to the first straight line L1, the conductor layer 23 is located on the right side, and the conductor part 23a is located on the left side. The dielectric part 22a and conductor part 23a described above are not included in the composite bulk member 20.

Similarly, the rightmost conductive fiber 21 located closest to the substrate 10 and on the rightmost side of the first member is specified, and the dielectric layer 22 and the conductor layer 23 covering the rightmost conductive fiber 21 are determined. Drawn is a second straight line L2 in contact with the outer edge of the conductor layer 23 and in parallel with the central axis AX. The second straight line L2 is intended to define the boundary between the dielectric layer 22 and the dielectric part 22a and the boundary between the conductor layer 23 and the conductor part 23a. With respect to the second straight line L2, the dielectric layer 22 is located on the left side, and the dielectric part 22a is located on the right side. With respect to the second straight line L2, the conductor layer 23 is located on the left side, and the conductor part 23a is located on the right side. The dielectric part 22a and conductor part 23a described above are not included in the composite bulk member 20.

Also in the case of the conductor layer 23 in contact with the conductive member, the outer edge of the conductor layer 23 can be similarly determined in consideration of the thickness of the conductor layer 23 covering the other conductive fibers 21. The conductive member is not included in the composite bulk member 20.

The composite bulk member 20 includes the plurality of conductive fibers 21, the dielectric layer 22, the conductor layer 23, and the space 24 that are present in the region sandwiched between the first straight line L1 and the second straight line L2. The respective tangent points (T1 and T2) between the first straight line L1 and the second straight line L2 and the composite bulk member 20 are points that indicate the outer edges of the composite bulk member 20 in the XZ section. The tangent points T1 and T2 are typically on the surface 10a of the substrate 10.

### Method for Determining Maximum Height Hₘₐₓ

The maximum height Hₘₐₓ is determined from, for example, the SEM image of the XZ section (No. 1) mentioned above. The end of the conductive fiber 21 farthest from the surface 10a of the substrate 10 in the Z direction is identified, and the distance in the Z direction between the end and the surface 10a is the maximum height Hₘₐₓ.

### Central Region R1 and Outer Peripheral Region R2

As shown in FIG. 1, in the XZ section, the outer peripheral regions R2 are disposed at two sites on one side and the other side (hereinafter, referred to also as a left side and a right side) in the X direction, with the central region R1 sandwiched therebetween. The outer peripheral regions R2 on one side and the other side face each other with the central region R1 interposed therebetween.

### Method for Determining Central Region R1 and Outer Peripheral Regions R2

The outer peripheral regions R2 are determined with the use of the SEM image of the XZ section (No. 1) mentioned above and the maximum height Hₘₐₓ. Points (P1 and P2) at distances that are twice the maximum height Hₘₐₓ from the tangent points T1 and T2 toward the central axis AX (toward the center C if the tangent points T1 and T2 are located on the surface 10a of the substrate 10 as shown) are plotted in the SEM image. The region on the left side from a third straight line L3 including the point P1 and extending in the Z direction is the outer peripheral region R2 on one side. The region on the right side from a fourth straight line L4 including the point P2 and extending in the Z direction is the outer peripheral region R2 on the other side. The region sandwiched between the third straight line L3 and the fourth straight line L4 is the central region R1.

### Area Occupancy Proportions S₁₁ and S₂₁

The area occupancy proportion S₁₁ is the total area occupancy proportion of the conductive fibers 21 and dielectric layer 22 in any part of the central region R1 in the section (for example, the XZ section) in the thickness direction. The area occupancy proportion S₂₁ is the total area occupancy proportion of the conductive fibers 21 and dielectric layer 22 in any part of the outer peripheral region R2 of the same section as mentioned above in the thickness direction. If the area occupancy proportion S₂₁ is lower than the area occupancy proportion S₁₁ in a part of the outer peripheral region R2, the area occupancy proportion S₂₁ in the other part of the outer peripheral region R2 in the section in the thickness direction has only to be higher than the area occupancy proportion S₁₁.

Above all, the area occupancy proportion S₂₁ may be higher than the area occupancy proportion S₁₁ in the whole outer peripheral regions R2 of any one section in the thickness direction.

The above-mentioned relationship between the area occupancy proportions S₁₁ and S₂₁ has only to be satisfied in a part of any one section in the thickness direction. In any one section in the thickness direction, both the outer peripheral regions R2 on one side and the other side may include a part where the area occupancy proportion S₂₁ is higher than the area occupancy proportion S₁₁. Thus, the mechanical strength of the composite bulk member 20 is further improved because the relatively weak central region R1 is protected from the left and the right.

In multiple different sections in the thickness direction, the outer peripheral regions R2 may include a part where the area occupancy proportion S₂₁ is higher than the area occupancy proportion S₁₁. In this case, the mechanical strength of the composite bulk member 20 is further improved. The fact that “. . . include a part where . . . higher . . . in multiple sections in the thickness direction” means that the outer peripheral regions R2 in at least two different sections in the thickness direction include a part where the area occupancy proportion S₂₁ is higher than the area occupancy proportion S₁₁. The fact is not intended to mean that the outer peripheral regions R2 need to include a part where the area occupancy proportion S₂₁ is higher than the area occupancy proportion S₁₁ in all of the sections in the thickness direction.

In at least two different sections in the thickness direction, both the outer peripheral regions R2 on one side and the other side may include a part where the area occupancy proportion S₂₁ is higher than the area occupancy proportion S₁₁.

The multiple different sections in the thickness direction are XZ sections, and can be YZ sections. The multiple different sections in the thickness direction can be obtained by rotating a XZ section around the central axis AX by less than 360 degrees.

The area occupancy proportion S₁₁ may be 0.1 or more, 0.15 or more, or 0.20 or more. The area occupancy proportion S₁₁ may be 0.5 or less, 0.4 or less, or 0.35 or less.

The area occupancy proportion S₂₁ may be 0.2 or more, 0.25 or more, or 0.30 or more. The area occupancy proportion S₂₁ may be 0.7 or less, 0.5 or less, or 0.45 or less.

Method for Calculating Area Occupancy Proportions S₁₁ and S₂₁

The area occupancy proportions S₁₁ and S₂₁ are calculated in the following manner with the use of the SEM image of the XZ section (No. 1) mentioned above. In the SEM image, the composite bulk member 20, the outer peripheral region R2, and the central region R1 are identified. In the composite bulk member 20, the conductive fiber 21, the dielectric layer 22, the conductor layer 23, and the filling resin (space 24) are distinguished.

The total area of the conductive fibers 21 and dielectric layer 22 in the right outer peripheral region R2 is divided by the area of the outer peripheral region R2 (that is, the total of the parts including the conductive fibers 21, the dielectric layer 22, the conductor layer 23, and the filling resin). Thus, the area occupancy proportion S₂₁ of the right outer peripheral region R2 is calculated. Similarly, the area occupancy proportion S₂₁ of the left outer peripheral region R2 is calculated. Similarly, the area occupancy proportion S₁₁ of the central region R1 is calculated.

The observation field of view in this case may have a size such that only a part of the central region R1 can be observed. Similarly, the observation field of view may have a size such that only a part of the outer peripheral region R2 can be observed. The size of the observation field of view may be, for example, about 1 μm×1 μm. Thus, the conductive fibers 21, the dielectric layer 22, the conductor layer 23, and the filling resin are more easily distinguished.

The area occupancy proportions S₁₁ and S₂₁ in multiple sections in the thickness direction are calculated in the following manner. First, for the composite bulk member 20 with the XZ section (No. 1) exposed, another section (for example, a YZ section: No. 2) in the thickness direction is further exposed by polishing, and an SEM image thereof is observed. The maximum height Hₘₐₓ is already measured, and thus, based on this maximum height Hₘₐₓ, the outer peripheral region R2 on one side is determined. Subsequently, image processing (with the use of EDX analysis in combination as necessary, the same shall apply hereinafter)) is performed as mentioned above to calculate the area occupancy proportion S₂₁ of the outer peripheral region R2 on one side appearing in the SEM image. While the section (No. 2) represents a part (half) of the section of the composite bulk member 20 in the thickness direction, the other part of the section (No. 2) may be considered to have the same configuration as a part in the XZ section. Thus, the area occupancy proportion S₂₁ of the outer peripheral region R2 on the other side can be also regarded as being the same as that on the one side. The area occupancy proportion S₁ₗ of the other part of the central region R1 can also be regarded as being the same as that appearing in the SEM image of the section (No. 2). Such an operation is repeated for the multiple different sections in the thickness direction as necessary. Then, the multiple SEM images are obtained, subjected to image processing or the like to calculate the area occupancy proportions S₁₁ and S₂₁ in the multiple sections in the thickness direction.

### Others

Whether the SEM image of the XZ section (No. 1) used as mentioned above is an SEM image of a section in the thickness direction of the substrate 10 or not can be confirmed with the thickness and width of the substrate 10 being observed. If the thickness of the substrate 10, measured from the SEM image, is larger than the original thickness of the substrate, it can be determined that the section is not a section in the thickness direction. “Being larger than the original thickness of the substrate” means that the thickness of the substrate 10 in the SEM image is 5% or more larger than the original thickness of the substrate 10. In addition, if the width of the substrate 10, measured from the SEM image, is smaller than the original width of the substrate (the distance between two intersections of: a straight line passing through the center of the substrate; and both ends of the substrate), it can be determined that the section is not a section in the thickness direction. “Being smaller than the original width of the substrate” means that the width of the substrate 10 in the SEM image is 5% or more smaller than the original width of the substrate 10.

From the viewpoint of capable of confirming that the SEM image is one in a section in the thickness direction, the field of view for the observation by the SEM is desirably wide (for example, 5 μm×5 μm or more) to the extent that the surface 10a, back surface 10b, and both ends of the substrate 10 can be confirmed. In contrast, the observation field of view for identifying and/or distinguishing the constituent elements of the composite bulk member 20 or calculating the area occupancy proportions may be narrower (for example, about 1 μm×1 μm).

The respective constituent elements will be described below.

### <<Conductive Fiber>>

In the present disclosure, the conductive fiber 21 is not particularly limited as long as the longitudinal direction dimension (length) thereof is (preferably significantly) larger than the maximum sectional dimension of a section perpendicular to the longitudinal direction, or the conductive fiber 21 has the form of a schematically elongated thread.

The average length of the conductive fibers 21 may be longer in terms of being capable of increasing the capacitance density per area. The average length of the conductive fibers 21 can be, for example, several μm or more, 20 μm or more, 50 μm or more, 100 μm or more, 500 μm or more, 750 μm or more, 1000 μm or more, or 2000 μm or more. The upper limit of the average length of the conductive fibers 21 can be appropriately selected, and the lengths of the conductive fibers 21 can be, for example, 10 mm or less, 5 mm or less, or 3 mm or less. In one aspect, the average length of the conductive fibers 21 is 50 μm or more. The average length of the conductive fibers 21 may be 50 μm to 3 mm.

The average length of the conductive fibers 21 can be calculated from the SEM image of the XZ section (No. 1) mentioned above. The average length of the conductive fibers 21 is the average value of the lengths of at least five or more of the conductive fibers 21.

The average number density (referred to also as “average number density”) of the conductive fibers 21 may be higher in terms of being capable of increasing the capacitance density per area and increasing the mechanical strength of the composite bulk member 20. The average number density N₂ of the conductive fibers 21 in the outer peripheral region R2 may be 10⁸ fibers/cm² or more. The average number density N₂ may be 10¹³ fibers/cm² or less, 10¹¹ fibers/cm² or less, or 10¹⁰ fibers/cm² or less.

In particular, the average length of the conductive fibers 21 may be 50 μm or more, and average number density N₂ in the outer peripheral region R2 may be 10⁸ fibers/cm² or more. Thus, in the outer peripheral region R2, the densely packed conductive fibers 21 are more likely to come into contact with the other conductive fibers 21, thereby making the mechanical strength of the composite bulk member 20 more likely to be increased.

The ratio N₂/N₁ of the average number density N₂ to the average number density N₁ of the plurality of conductive fibers 21 in the central region R1 is, for example, 2 or more. Thus, the mechanical strength of the composite bulk member 20 is more likely to be increased. The ratio N₂/N₁ may be 5 or more, 10 or more, or 50 or more. The ratio N₂/N₁ may be 1000 or less, 500 or less, or 100 or less.

Method for Calculating Average Number Densities N₁ and N₂

The average number densities of the conductive fibers 21 can be calculated with the use of the sample used for calculating the area occupancy proportions S₁₁ and S₂₁. First, the XY section of the sample at a first position where the height H from the surface 10a of the substrate 10 is 20% or less (typically, 10% or less) of the maximum height Hₘₐₓ is exposed by polishing. In this case, the XY section may be obtained by cutting or without cutting the dielectric part 22a or the conductor part 23a. While the obtained XY section shows a part (which can be half or less) of the XY section of the composite bulk member 20, the other part of the XY section may be also considered to have the same configuration as the part of the obtained XY section.

The obtained XY section is observed with a SEM, and the central region R1 and the outer peripheral region R2 are determined in the following manner. As shown in FIG. 3, the SEM image shows the outer edge of the composite bulk member 20. One side of the outer edge of the composite bulk member 20 in the SEM image is, however, a cutting line CL for exposing the XZ section. The SEM image may further show the surface 10a of the substrate 10, or the dielectric part 22a or conductor part 23a covering the surface 10a.

First, as mentioned above, the composite bulk member 20 is distinguished by image processing into the conductive fibers 21, the dielectric layer 22, the conductor layer 23, and the filling resin (space 24). Next, parts (points) of the plurality of conductive fibers 21 on the outermost side of the composite bulk member 20 are identified in the SEM image. In the XY section mentioned above, the outer edge of the composite bulk member 20 and the outer edge of the substrate 10 may be considered to be similar to each other, excluding the cutting line CL. Drawn is a line including the multiple plotted points and excluding the cutting line CL to be similar to the outer edge of the substrate 10. This line is the outer edge of the composite bulk member 20 in the XY section.

From any point on the obtained outer edge toward the opposite outer edge, a point at a distance that is twice the already calculated maximum height Hₘₐₓ is plotted. Such an operation is repeated for multiple different points (for example, four points) on the outer edge, and a line including the multiple plotted points and excluding the cutting line CL to be similar to the outer edge of the composite bulk member 20 is drawn. This line is the boundary between the outer peripheral region R2 and the central region R1. The region from the line to the outer edge of the composite bulk member 20 is the outer peripheral region R2, and the inner region surrounded by the line and the cutting line CL is the central region R1.

In the composite bulk member 20, the outer peripheral region R2 is disposed so as to surround the periphery of the central region R1 as can be seen from FIG. 3. A part of the outer edge of the composite bulk member 20 are indicated by straight lines L5 and L6. A part of the boundary between the outer peripheral region R2 and the central region R1 is indicated by straight lines L7 and L8. The straight lines L5 and L6 correspond to straight lines including the tangent points T1 and T2 and following in the Y direction in FIG. 1. The straight lines L7 and L8 correspond to straight lines including the points P1 and P2 and following in the Y direction in FIG. 1.

The number of the conductive fibers 21 present in a part (for example, a region of 5 μm×5 μm) of the determined outer peripheral region R2 is counted to determine the number (number density) of the conductive fibers 21 per unit area. Such an operation is repeated to obtain the number density in five or more fields of view, and the average value thereof is defined as the average number density N₂ of the conductive fibers 21 in the outer peripheral region R2. The average number density N₁ of the conductive fibers 21 in the central region R1 is also calculated in the same manner.

Whether the SEM image of the XY section used as mentioned above is an SEM image of a section in parallel with the in-plane direction of the substrate 10 or not can be confirmed with the sectional shape of the conductive fiber 21. At the first position mentioned above, most of the conductive fibers 21 extend in the Z direction, and the sectional shapes thereof are substantially circular. Thus, when the section of the conductive fiber 21 is flattened, it can be determined that the section is not an XY section. The fact that “the section of the conductive fiber 21 is flattened” means that the ratio (major axis/minor axis) of the major axis of the section of the conductive fiber 21 to the minor axis thereof is 1.41 or more. The major axis is the longest one of diameters passing through the center of the section of the conductive fiber 21. The minor axis is the shortest one of diameters passing through the center of the section of the conductive fiber 21. The center of the section of the conductive fiber 21 is the center of the smallest circle enclosing the section of the conductive fiber 21.

The maximum sectional dimension of the conductive fiber 21 can be, for example, 0.1 nm or more, 1 nm or more, or 10 nm or more. The maximum sectional dimension of the conductive fiber 21 can be, for example, 1 nm or more, or 10 nm or more. The maximum sectional dimension of the conductive fiber 21 can be less than 1000 nm, 800 nm or less, or 600 nm or less.

The maximum sectional dimension of the conductive fiber 21 can be calculated from the SEM image of the XY section used for the calculation of the average number densities N₁ and N₂. The maximum sectional dimension of the conductive fiber 21 is the average value of the maximum sectional dimensions of at least 5 or more of the conductive fibers 21.

The conductive fibers 21 may be conductive nanofibers (with a maximum sectional dimension of nanoscale (1 nm or more and less than 1000 nm)). The conductive nanofibers may be, for example, conductive nanotubes (hollow, preferably cylindrical) or conductive nanorods (solid, preferably columnar). Nanorods with electrical conductivity (including semiconductivity) are also referred to as nanowires.

Examples of the conductive nanofibers that can be used according to the present disclosure include carbon nanofibers. Examples of the conductive nanotubes that can be used according to the present disclosure include metal-based nanotubes, organic conductive nanotubes, and inorganic conductive nanotubes. Typically, the conductive nanotubes can be carbon nanotubes or titania carbon nanotubes. Examples of the conductive nanorods (nanowires) that can be used according to the present disclosure include silicon nanowires, metal nanowires (in particular, silver nanowires), and conductive polymer wires.

The conductive fibers 21 may have higher strength than the dielectric layer 22 in that the mechanical strength of the composite bulk member 20 is more likely to be increased. The strength of the conductive fiber 21 may be 5 MPa/(nm)² to 150 Gpa/(nm)². Thus, the conductive fibers 21 can be expected to function as a core material of the composite bulk member 20, and also keep cracks from being generated in the composite bulk member 20. The strength of the conductive fiber 21 may be 10 MPa/(nm)² or more, and may be 10 Gpa/(nm)² or more. The strength of the conductive fiber 21 may be 100 Gpa/(nm)² or less.

Examples of the conductive fiber 21 with the strength of 5 MPa/(nm)² to 150 Gpa/(nm)² include at least one selected from the group consisting of carbon nanotubes, metal nanowires, and conductive polymer wires.

Above all, the conductive fibers 21 may be carbon nanotubes. Carbon nanotubes have electrical conductivity and thermal conductivity.

The chirality of the carbon nanotubes is not particularly limited, and may have either a semiconductor type or a metal type, or a mixture thereof may be used. From the viewpoint of reducing the resistance value, the ratio of the metal type is preferably high.

The number of layers of the carbon nanotube is not particularly limited, and the carbon nanotube may be either a SWCNT (single-walled carbon nanotube) that has one layer or a MWCNT (multi-walled carbon nanotube) that has two or more layers.

The plurality of conductive fibers 21 may be vertically aligned carbon nanotubes (VACNTs). A VACNT has a large specific surface area. In addition, VACNTs can be manufactured by growth of the VACNTs vertically aligned on the substrate 10 as described later, and thus have the advantage of facilitating the control the maximum height Hₘₐₓ.

### <<Substrate>>

The substrate 10 has two main surfaces (surface 10a and back surface 10b) that face each other, and may have the form of, for example, a plate (substrate), a foil, a film, a block, or the like.

The material constituting the substrate 10 can be selected appropriately, as long as the material has electrical conductivity, and can be electrically connected to the plurality of conductive fibers 21. The material can be, for example, a semiconductor material such as silicon, a conductive material such as a metal (copper, aluminum, or nickel), or an insulating (or relatively poorly conductive) material such as a ceramic (silicon oxide) or a resin. The substrate 10 may be composed of one type of material, or composed of a mixture of two or more types of materials, or may be a composite composed of two or more types of materials. The material constituting the substrate 10 is preferably a metal because the metal is easily used as a contact with the outside, is capable of reducing the resistance value, and can withstand high temperatures.

The thickness of the substrate 10 is not particularly limited, and can vary depending on the application of the capacitor 1. The substrate 10 may be provided with an electrode for making contact with the outside and a wiring for ensuring electrical conduction.

### <<Dielectric Layer>>

The dielectric material constituting the dielectric layer 22 can be selected appropriately. Examples thereof include a silicon dioxide, an aluminum oxide, a silicon nitride, a tantalum oxide, a hafnium oxide, a barium titanate, and a lead zirconate titanate. These materials may be used alone, or two or more thereof may be used (for example, as a laminate).

The thickness of the dielectric layer 22 may be 10 nm or more, and may be 15 nm or more. The thickness of the dielectric layer is 10 nm or more, thereby making it possible to enhance the insulation property and allowing leakage current to be reduced. The thickness of the dielectric layer 22 may be 1 μm or less, 100 nm or less, or 70 nm or less. The thickness of the dielectric layer 22 is 1 μm or less, thereby allowing a higher electrostatic capacitance to be obtained. In one aspect, the thickness of the dielectric layer 22 is 10 nm to 1 μm.

The thickness of the dielectric layer 22 can be calculated from the SEM image of the XY section used for the calculation of the average number densities N₁ and N₂. The thickness of the dielectric layer 22 is the average value of the thicknesses of the dielectric layer 22 covering at least five or more of the conductive fibers 21.

If present, the material constituting the dielectric part 22a and the thickness of dielectric part 22a can be the same as those of the dielectric layer 22.

### <<Conductor Layer>>

Examples of the conductive material constituting the conductor layer 23 include a metal, a conductive polymer (which is a polymer material with conductivity and/or imparted with conductivity, and is referred to also as an organic conductive material). These materials may be used alone, or two or more thereof may be used. The conductor layer 23 may be a laminate of multiple layers that differ in conductive material.

Examples of the metal include silver, gold, copper, platinum, aluminum, and an alloy containing at least two thereof. Examples of the conductive polymer include a PEDOT (polyethylene dioxythiophene), a PPy (polypyrrole), and a PANI (polyaniline), and these polymers may be appropriately doped with a dopant such as an organic sulfonic acid-based compound, for example, a polyvinyl sulfonic acid, a polystyrene sulfonic acid, a polyallyl sulfonic acid, a polyacrylic sulfonic acid, a polymethacrylic sulfonic acid, a poly-2-acrylamide-2-methylpropane sulfonic acid, or a polyisoprene sulfonic acid.

The thickness of the conductor layer 23 may be 3 nm or more, and may be 10 nm or more. The thickness of the conductor layer 23 is 3 nm or more, thereby allowing the resistance value of the conductor layer 23 itself to be reduced. The thickness of the conductor layer 23 may be 500 nm or less, and may be 100 nm or less. In one aspect, the thickness of the conductor layer 23 is 3 nm to 500 nm.

The thickness of the conductor layer 23 can be calculated from the SEM image of the XY section used for the calculation of the average number densities N₁ and N₂. The thickness of the conductor layer 23 is the average value of the thicknesses of the conductor layer 23 covering at least five or more of the conductive fibers 21.

If present, the material constituting the conductor part 23a and the thickness of conductor part 23a can be the same as those of the conductor layer 23.

### <<Space>>

The space 24 is formed among the covered conductive fibers 21. Increasing the area occupancy proportion S₂₁ in the outer peripheral region R1 reduces the space 24, thereby increasing the mechanical strength of the composite bulk member 20.

### <<Conductive Member>>

The capacitor 1 can have the conductive member in contact with the conductor layer 23. The conductive member is electrically connected to the conductor layer 23, and plays a role for extending the electrode to the outside of the capacitor 1.

The conductive member has no contact with the conductive fibers 21, the dielectric layer 22, or the substrate 10. The boundary between the conductive member and the conductor layer 23 can be confirmed with an SEM image. Alternatively, the boundary between the conductive member and the conductor layer 23 can be identified from elemental analysis by EDX. Furthermore, the boundary between the conductive member and the conductor layer 23 may be determined from the thickness of the conductor layer 23 of a part that has no contact with the conductive member.

The conductive member is formed, for example, by applying/supplying a carbon paste or a conductive polymer material to a predetermined surface/part. The carbon paste and the conductive polymer material are typically relatively high in viscosity, and are thus less likely to penetrate into the space 24 and less likely to reach deep parts (for example, the surface 10a of the substrate 10) of the space 24. Accordingly, the space 24 is maintained among the covered conductive fibers 21.

### (Manufacturing Method)

The capacitor 1 according to the present embodiment can be obtained, for example, by a manufacturing method including the following:
attaching a catalyst to the surface 10a of the substrate 10 such that the attachment amount on an outer edge is larger than that on a central part;
allowing a plurality of conductive fibers 21 to grow on the surface 10a of the substrate 10 with the catalyst as a nucleus to prepare a forest including the plurality of conductive fibers 21 disposed on the surface 10a of the substrate 10 and each directly joined, at one end thereof, to the substrate 10;
forming the dielectric layer 22 (and the dielectric part 22a if present, the same shall apply hereinafter) covering the surface of the plurality of conductive fibers 21 by a sol-gel method; and
forming the conductor layer 23 (and conductor part 23a if present, the same shall apply hereinafter) covering the surface of the dielectric layer 22.

Hereinafter, the steps (a) to (d) will be described in more detail.

### Step (a)

First, a catalyst is attached to the surface 10a of the substrate 10. Vertically aligned carbon nanotubes (VACNTs, conductive fibers 21) grow with this catalyst as a nucleus. The catalyst is attached such that the attachment amount on the outer edge of the surface 10a of the substrate 10 is larger than that on the central part thereof, thereby allowing a dense part of VACNTs to be provided on the edge side of the forest obtained.

The substrate 10 may be a synthetic substrate for causing VACNTs to grow. In general, the material of the synthetic substrate is not particularly limited, and for example, silicon oxide, silicon, gallium arsenide, aluminum, or SUS can be used. In the present embodiment, the substrate 10 with conductivity is used as the synthetic substrate.

As the catalyst, iron, nickel, platinum, cobalt, an alloy containing these metals, or the like is used. Methods such as chemical vapor deposition (CVD), sputtering, physical vapor deposition (PVD), atomic layer deposition (ALD) can be used for the method for attaching the catalyst to the substrate 10, and in some cases, such a technique may be combined with a technique such as lithography or etching.

### Step (b)

Next, a plurality of VACNTs are allowed to grow on the surface 10a of the substrate 10 with the catalyst as a nucleus. Thus, a forest including the VACNTs each directly joined, at one end thereof, to the substrate 10 is obtained.

The method for the VACNT growth is not particularly limited, and CVD, plasma-enhanced CVD, or the like can be used under heating as necessary. The gas used is not particularly limited, and for example, at least one selected from the group consisting of carbon monoxide, methane, ethylene, and acetylene, or a mixture of at least one thereof and hydrogen and/or ammonia can be used. If desired, moisture may be present in the ambient atmosphere for VACNT growth. Thus, VACNTs grow with the catalyst as a nucleus on the substrate 10. The end of the VACNT on the side closer to the surface 10a of the substrate 10 is a fixed end that is fixed to the substrate 10 (typically with the catalyst interposed therebetween), and the opposite end of the VACNT is a free end that is a growth point. The length and diameter of the VACNT may vary depending on changes in parameters such as a gas concentration, a gas flow rate, and a temperature. More specifically, the length and diameter of the VACNT can be adjusted by appropriately selecting these parameters.

As a result, a forest of VACNTs is prepared on the substrate 10. Strictly speaking, the length of each of VACNTs in the obtained forest can vary (for example, cause in-plane variations) on the free end side due to a difference in growth rate or the like. When the VACNTs are allowed to grow on the substrate 10 with the catalyst attached thereto, the growth of some carbon nanotubes (CNTs) may be stopped due to the catalyst deactivated in the process of the VACNT synthesis. The CNTs whose growth is stopped are entangled with the subsequently growing CNTs and then pulled, thereby making the fixed ends away from the substrate 10 and then pulled up toward the tips of the VACNTs.

The plurality of VACNTs (conductive fibers 21) obtained as mentioned above are disposed on the substrate 10, and each directly joined, at one end thereof, to the substrate 10. As understood from the above-mentioned description, however, some of the CNTs may be indirectly joined to the substrate 10.

### Step (c)

Subsequently, the dielectric layer 22 covering at least the surface of the VACNTs is formed by a sol-gel method.

The thickness of the dielectric layer 22 to be formed can be controlled by appropriately selecting or setting the conditions for implementing the sol-gel method. For example, the prepared composition of the liquid for use in the sol-gel method, the solvent (for example, water, ethanol, isopropanol, or acetone) for use in the preparation, the film formation time, the stirring speed, the temperature, and the like may be selected or set appropriately.

Thereafter, the dielectric layer 22 is formed by drying for the removal of the solvent.

### Step (d)

Subsequently, the conductor layer 23 covering the surface of the dielectric layer 22 is formed.

The film formation method for the conductor layer 23 is not particularly limited, and a liquid phase film formation method, a vapor phase film formation method, and a combination thereof may be used. The liquid phase film formation method can be, for example, a sol-gel method, plating, or the like. The vapor phase film formation method can be ALD, sputtering, CVD, or the like.

For example, the conductor layer 23 can be formed by a liquid phase film formation method with the use of a conductive polymer. More specifically, the conductor layer 23 can be formed by applying/supplying (for example, performing application, immersion, or the like), to a predetermined surface/part, a liquid composition that has a conductive polymer dissolved or dispersed in an organic solvent. The conductive polymer is easily allowed to penetrate into spaces formed between the plurality of VACNTs covered with the dielectric layer 22, and the conductor layer 23 can be formed appropriately also in deep parts (for example, bottom parts) of the spaces.

As described above, the capacitor 1 shown in FIGS. 1, 2, and 3 can be manufactured.

### Modification Example 1

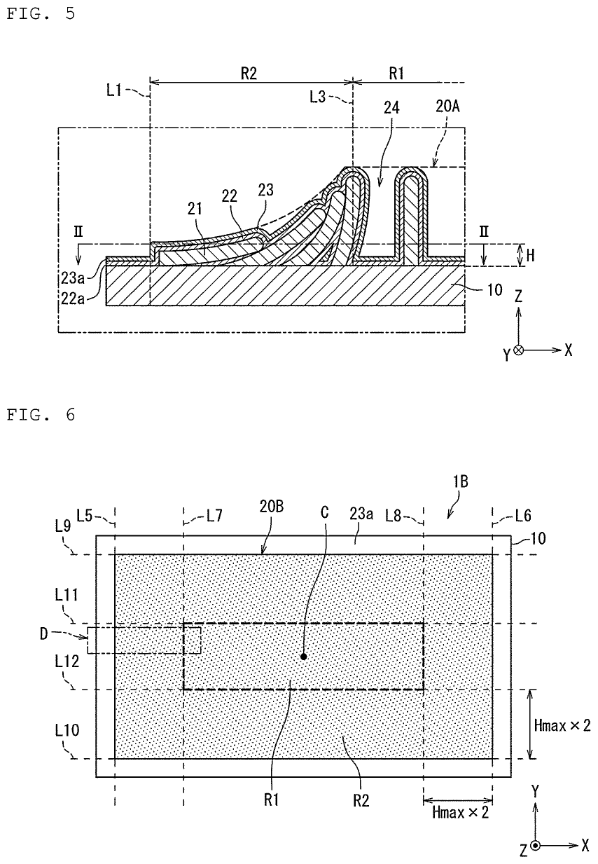

FIG. 4 is a schematic sectional view of a capacitor according to Modification Example 1 of Embodiment 1. FIG. 4 is a sectional view corresponding to FIG. 1. FIG. 5 is an enlarged view of a part B in FIG. 4, corresponding to FIG. 2.

Modification Example 1 is different from Embodiment 1 in the outer shape of the composite bulk member. This different configuration will be described below. The other configurations are the same as those of Embodiment 1, and are denoted by the same reference symbols as those of the Embodiment 1, and will be omitted from description.

As shown in FIG. 4, in a section in the thickness direction (an XZ section herein), parts of the outer edges of outer peripheral regions R2 of the capacitor 1A are inclined in the X direction. In this case, as shown in FIG. 5, the conductive fibers 21 are inclined with respect to the z direction or bent in the X direction in the outer peripheral region R2. Thus, the space 24 present in the outer peripheral region R2 is crushed and reduced. Thus, the outer peripheral region R2 includes a part where the area occupancy proportion S₂₁ of the conductive fibers 21 and dielectric layer 22 is higher than the area occupancy proportion S₁₁ of the conductive fibers 21 and the dielectric layer 22 in the central region R1.

In addition, the conductive fibers 21 are inclined with respect to the Z direction or bent in the X direction, thereby allowing at least two of the conductive fibers 21 to be brought into contact with each other with the dielectric layer 22 interposed therebetween or without the dielectric layer 22 interposed therebetween in the outer peripheral region R2. More specifically, the plurality of conductive fibers 21 are located so as to support each other in the outer peripheral region R2, and thus, the composite bulk member 20A is less likely to be deformed by external forces. This also further improves the mechanical strength of the composite bulk member 20A.

### (Manufacturing Method)

The capacitor 1A can be obtained, for example, by a manufacturing method including the following:
(a′) preparing a forest including a plurality of VACANTs (conductive fibers 21) disposed on the surface 10a of the substrate 10 and each directly joined, at one end thereof, to the substrate 10;
(b′) tilting the VACANTs outside the forest towards the center;
(c) forming the dielectric layer 22 covering the surface of the VACANTs by a sol-gel method; and
(d) forming the conductor layer 23 covering the surface of the dielectric layer 22.

The step (b′) will be described in detail below. The step (a′) is performed in the same manner as the steps (a) and (b) according to Embodiment 1, except that the catalyst is uniformly attached to the whole surface 10a of the substrate 10. The steps (c) and (d) are performed in the same manner as the steps (c) and (d) according to Embodiment 1.

Step (b′)

The VACNTs at an edge of the forest obtained is tilted toward the center.

Immersing the forest in a suitable solvent allows the VACNTs at the edge of the forest be to tilted towards the center. Immersing the forest in an appropriate solvent makes the VACNTs, particularly outside the forest more likely to be agglomerated with each other. In contrast, the VACNTs near the center of the forest are likely to be kept upright. As a result, the VACNTs at the edge are inclined toward the center.

The solvent is selected in consideration of the wettability of the VACNTs. When the wettability of the VACNTs is excessively low, the agglomeration of the VACNTs are less likely to proceed. In contrast, when the wettability of the VACNTs is excessively high, the agglomeration of the VACNTs excessively proceeds, thereby making the composite bulk member 20A suitable for the capacitor 1A less likely to be obtained. Examples of the suitable solvent include water, ethanol, isopropanol, and acetone. Above all, ethanol may be used.

A surfactant may be added to the solvent. Thus, the wettability of the VACNTs is easily adjusted. The surfactant may be anionic. The surfactant is selected appropriately in consideration of the charge and molecular weight of the hydrophilic group. Examples of the surfactant include a sodium dodecyl sulfate, a cetyltrimethylammonium bromide, and a sodium dodecylbenzenesulfonate. The amount of the surfactant added is set appropriately in consideration of the wettability of the VACNTs.

The conditions for the immersion are also set in consideration of the wettability of the VACNTs. The immersion may be performed, in terms of suppressing excessive agglomeration, by putting the substrate 10 provided with a forest into a solvent at room temperature (23° C.±3° C.) at a speed of 2 to 10 mm/second (typically, 5 mm/s) such that the angle formed by the substrate 10 and the liquid level is approximately 90 degrees.

The agglomeration of the forest is also described in Non-Patent Document 1.

A material for the dielectric layer 22 may be added to the solvent. Thus, the step (c) can be performed with the use of the bath used in the step (b′) as it is. The step (b′) and the step (c) are performed simultaneously or continuously in the same bath. In other words, the agglomeration of the VACNTs and the adhesion of the material for the dielectric layer 22 proceed simultaneously or continuously. The material for the dielectric layer 22 adheres to the surface of the VACNTs, thereby making the VACNTs likely to be kept appropriately agglomerated with each other, and then, further agglomeration is kept from proceeding due to subsequent drying. The step (b′) and the step (c) may be performed simultaneously or continuously from the viewpoint of easily controlling the agglomeration as described above. In this case, the film formation time may be 1 to 3 hours (typically 1.5 hours), and the stirring speed may be 150 to 500 rpm (typically 300 rpm).

As described above, the capacitor 1A shown in FIGS. 4 and 5 can be manufactured.

### Embodiment 2

Embodiment 2 is different from Embodiment 1 in the elements for use in calculating the area occupancy proportions. Specifically, in calculating the area occupancy proportions, the area of the conductor layer 23 is used in addition to the areas of the conductive fibers 21 and the dielectric layer 22. The other configurations are the same as those of Embodiment 1, and are denoted by the same reference symbols as those of the Embodiment 1, and will be omitted from description. Embodiment 2 will be described with reference to FIGS. 1 to 3, as in Embodiment 1.

In Embodiment 2, the outer peripheral region R2 includes a part where the total area occupancy proportion S₂₂ of the conductive fibers 21, dielectric layer 22, and the conductor layer 23 is higher than the total area occupancy proportion S₁₂ of the conductive fibers 21, the dielectric layer 22, and the conductor layer 23 in the central region R1.

The fact that “the area occupancy proportion S₂₂ is higher than the area occupancy proportion S₁₂” can be also paraphrased as the fact that “the space present in outer peripheral region R2 is smaller than space present in central region R1”. Thus, as compared with a composite bulk member that has a uniform area occupancy proportion, the composite bulk member 20 according to the present embodiment has higher mechanical strength in the outer peripheral regions R2. Also in the present embodiment, increasing the area occupancy proportion S₂₂ in only the outer peripheral region R2 allows the mechanical strength of the composite bulk member 20 to be improved while keeping the performance of the capacitor 1 from being degraded.

The fact that “the area occupancy proportion S₂₂ is higher” means that the difference between the above-mentioned area occupancy proportions S₁₂ and S₂₂ is 5% or more. More specifically, the fact means S₂₂/S₁₂≥1.05. S₂₂/S₁₂ may be 1.2 or more, 2 or more, or 5 or more.

The case of S₂₂/S₁₂≥1.05 may be considered as the above-mentioned relationship of S₂₁/S₁₁≥1.05 also being satisfied. The case of S₂₁/S₁₁≥1.05 may be considered as the relationship of S₂₂/S₁₂≥1.05 also being satisfied.

The area occupancy proportions S₁₂ and S₂₂ can be calculated in the same manner as in Embodiment 1, except that the total area of the conductive fibers 21, the dielectric layer 22, and the conductor layer 23 is divided by the area of the central region R1 or the outer peripheral region R2.

The area occupancy proportion S₁₂ may be 0.10 or more, 0.15 or more, or 0.20 or more. The area occupancy proportion S₁₂ may be 0.50 or less, 0.40 or less, or 0.35 or less.

The area occupancy proportion S₂₂ may be 0.2 or more, 0.25 or more, or 0.30 or more. The area occupancy proportion S₂₂ may be 0.70 or less, 0.50 or less, or 0.45 or less.

### Modification Example 2

Modification Example 2 is different from Embodiment 2 in the outer shape of the composite bulk member. This different configuration is the same as the difference between Embodiment 1 and the Modification Example 1. Modification Example 2 will be described with reference to FIGS. 4 and 5, as in Modification Example 1.

As in Modification Example 1, in a capacitor 1A according to Modification Example 2, the conductive fibers 21 are inclined with respect to the Z direction or bent in the X direction in the outer peripheral region R2 of the XZ section. Thus, the space 24 present in the outer peripheral region R2 is crushed and reduced. The outer peripheral region R2 includes a part where the total area occupancy proportion S₂₂ of the conductive fibers 21, dielectric layer 22, and the conductor layer 23 is higher than the total area occupancy proportion S₁₂ of the conductive fibers 21, the dielectric layer 22, and the conductor layer 23 in the central region R1.

### Embodiment 3

Embodiment 3 is different from Embodiment 1 in the elements the section for use in calculating the area occupancy proportions. This different configuration will be described below. The other configurations are the same as those of Embodiment 1, and are denoted by the same reference symbols as those of the Embodiment 1, and will be omitted from description.

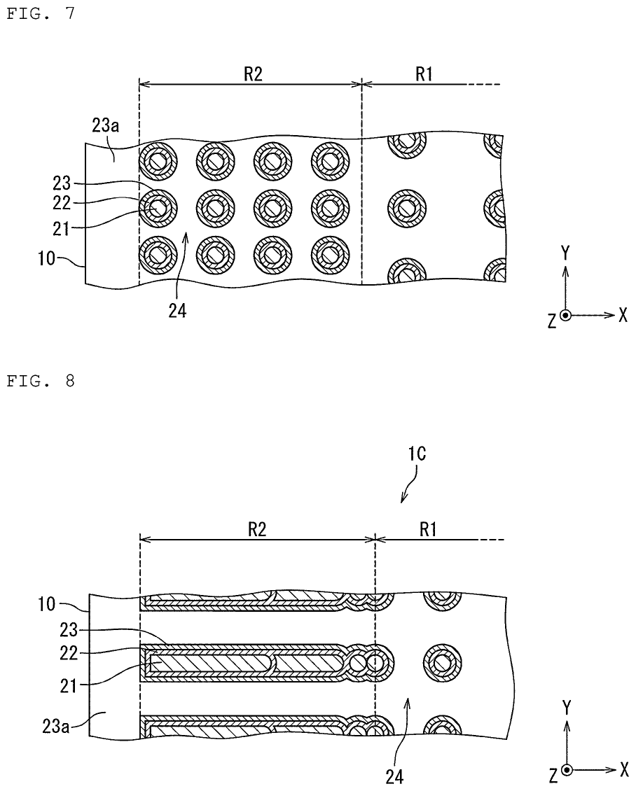

FIG. 6 is a schematic sectional view of a capacitor according to Embodiment 3. FIG. 6 shows a section in an in-plane direction of the substrate 10. FIG. 6 shows therein, for the sake of convenience, the substrate 10 and the outer edge of a composite bulk member 20B, while conductive fibers 21, a dielectric layer 22, a conductor layer 23, a space 24 are omitted. FIG. 7 is an enlarged view of a part D of FIG. 6. FIG. 7 schematically shows therein the conductive fibers 21 sequentially covered with the dielectric layer 22 and the conductor layer 23. For the sake of convenience, FIG. 7 shows only parts of the substrate 10, conductive fibers 21, dielectric layer 22, conductor layer 23, and space 24. An example of a section of the capacitor according to Embodiment 3 in the thickness direction of the substrate 10 is shown in FIGS. 1 and 2. FIG. 7 corresponds to the I-I section of FIG. 2.

### (Configuration)

The conductive fiber 21 constituting a composite bulk member 20B has a maximum height Hₘₐₓ. The composite bulk member 20B has, in an XY section, an outer peripheral region R2 in a range from the outer edge of the composite bulk member 20B up to twice the maximum height Hₘₐₓ, and a central region R1 surrounded by the outer peripheral region R2.

As shown in FIG. 7, in the XY section, the conductive fibers 21 in the outer peripheral region R2 is more densely packed than those in the central region R1. Thus, the outer peripheral region R2 includes a part where the total area occupancy proportion S₂₃ of the conductive fibers 21, dielectric layer 22, and the conductor layer 23 is higher than the total area occupancy proportion S₁₃ of the conductive fibers 21, the dielectric layer 22, and the conductor layer 23 in the central region R1.

The fact that the outer peripheral region R2 “includes a part where the area occupancy proportion S₂₃ is higher” refers to the fact that the area occupancy proportion S₂₃ in at least a part of the outer peripheral region R2 in any one XY section is higher than the area occupancy proportion S₁₃ in a part of the central region R1 in the same XY section. The fact is not intended to mean that the area occupancy proportion S₂₃ needs to be higher than the area occupancy proportion S₁₃ in the whole XY section.

The fact that “the area occupancy proportion S₂₃ is higher than the area occupancy proportion S₁₃” can be paraphrased as the fact that “the space 24 present in outer peripheral region R2 is narrower than space 24 present in central region R1”. Thus, as compared with a composite bulk member that has a uniform area occupancy proportion, the composite bulk member 20B according to the present embodiment has higher mechanical strength in the outer peripheral region R2. Also in the present embodiment, increasing the area occupancy proportion S₂₃ in only the outer peripheral region R2 allows the mechanical strength of the composite bulk member 20B to be improved while keeping the performance of the capacitor 1B from being degraded. The fact that “the area occupancy proportion S₂₃ is higher than the area occupancy proportion S₁₃” can also be paraphrased as the fact that “the number density of the conductive fibers 21 present in the outer peripheral region R2 is higher than the number density of the conductive fibers 21 present in the central region R1”.

The fact that “the area occupancy proportion S₂₃ is higher” means that the difference between the area occupancy proportions S₁₃ and S₂₃ is 5% or more. More specifically, the fact means S₂₃/S₁₃≥1.05. S₂₃/S₁₃ may be 1.2 or more, 2 or more, or 5 or more.

The area occupancy proportion S₁₃ is the total area occupancy proportion of the conductive fibers 21 and dielectric layer 22 in any part of the central region R1 of any one XY section. The area occupancy proportion S₂₃ is the total area occupancy proportion of the conductive fibers 21 and dielectric layer 22 in any part of the outer peripheral region R2 of the same XY section as mentioned above. If the area occupancy proportion S₂₃ is lower than the area occupancy proportion S₁₃ in a part of the outer peripheral region R2, the area occupancy proportion S₂₃ in the other part of the outer peripheral region R2 in the XY section has only to be higher than the area occupancy proportion S₁₃.

Above all, the area occupancy proportion S₂₃ may be higher than the area occupancy proportion S₁₃ in the whole outer peripheral region R2 of any one XY section.

The above-mentioned relationship between the area occupancy proportions S₁₃ and S₂₃ has only to be satisfied in a part of any one XY section. In any one XY section, the outer peripheral region R2 on both one side and the other side with the central region R1 interposed therebetween may include a part where the area occupancy proportion S₂₃ is higher than the area occupancy proportion S₁₃. Thus, the mechanical strength of the composite bulk member 20B is further improved.

In multiple different XY sections, the outer peripheral region R2 may include a part where the area occupancy proportion S₂₃ is higher than the area occupancy proportion S₁₃. In this case, the mechanical strength of the composite bulk member 20B is further improved. The fact that “. . . include a part where . . . higher . . . in multiple XY sections” means that the outer peripheral regions R2 in at least two different XY sections include a part where the area occupancy proportion S₂₃ is higher than the area occupancy proportion S₁₃. The fact is not intended to mean that the outer peripheral region R2 needs to include a part where the area occupancy proportion S₂₃ is higher than the area occupancy proportion S₁₃ in all of the XY sections.

In at least two different XY sections, the two outer peripheral regions R2 facing each other with the central region R1 interposed therebetween may include a part where the area occupancy proportion S₂₃ is higher than the area occupancy proportion S₁₃.

The area occupancy proportion S₁₃ may be 0.08 or more, 0.10 or more, or 0.15 or more. The area occupancy proportion S₁₃ may be 0.50 or less, 0.40 or less, or 0.30 or less.

The area occupancy proportion S₂₃ may be 0.15 or more, 0.20 or more, or 0.25 or more. The area occupancy proportion S₂₃ may be 0.70 or less, 0.50 or less, or 0.40 or less.

### Method for Determining Maximum Height Hₘₐₓ

The maximum height Hₘₐₓ is determined in the same manner as in Embodiment 1 from an SEM image of an XZ section obtained in the same manner as in Embodiment 1.

### Central Region R1 and Outer Peripheral Region R2

In the XY section, the outer peripheral region R2 is disposed so as to surround the periphery of the central region R1.

### Method for Determining Central Region R1 and Outer Peripheral Regions R2

The central region R1 and the outer peripheral region R2 are determined by the same method as that for the determination of the central region R1 and the outer peripheral region R2, performed in Embodiment 1 for calculating the average number densities N₁ and N₂, with the use of the sample used in determining the maximum height Hₘₐₓ. Regarding this method, reference can be made to FIG. 3. For the sample mentioned above, an XZ section of the capacitor 1B and a half of an XY section thereof are exposed.

### Method of Determining Opposite Outer Peripheral Region R2

The opposite outer peripheral region R2 can likewise be determined from the XY section of the sample used in determining the maximum height Hₘₐₓ. While this XY section shows a part (which can be half or less) of the XY section of the composite bulk member 20B, the other part of the XY section may be also considered to have the same configuration as the part of the obtained XY section. The XY section is schematically shown in FIG. 3. FIGS. 3 and 6 correspond to each other, and it is FIG. 6 that is an example of supplementing the other part of the XY section of the composite bulk member 20B, removed by cutting in FIG. 3. The opposite outer peripheral region R2 may be determined with the use of FIG. 6.

As in FIG. 3, FIG. 6 shows straight lines L5 and L6 for a part of the outer edge of the composite bulk member 20B and straight lines L7 and L8 for a part of the boundary between the outer peripheral region R2 and the central region R1. Furthermore, FIG. 6 shows straight lines L9 and L10 for the other part of the outer edge of the composite bulk member 20B and straight lines L11 and L12 for the other part of the boundary between the outer peripheral region R2 and the central region R1. When the outer edge of the composite bulk member 20B includes curves, the straight lines L5 and L6 correspond to straight line respectively including the left and right ends of the composite bulk member 20B and following in the Y direction. Similarly, the straight lines L9 and L10 correspond to straight line respectively including the ends of the composite bulk member 20B in the Y direction and following in the X direction. When the boundary between the outer peripheral region R2 and the central region R1 includes curves, the straight lines L7 and L8 correspond to straight line respectively including the left and right ends of the central region R1 and following in the Y direction. Similarly, the straight lines L11 and L12 correspond to straight line respectively including the ends of the central region R1 in the Y direction and following in the X direction.

In FIG. 6, the opposite outer peripheral region R2 can be determined to be a combination of “the part between the straight lines L5 and L7 of the outer peripheral region R2” and “the part between the straight lines L8 and L10 of the outer peripheral region R2”, and a combination of “the part between the straight lines L9 and L11 of the outer peripheral region R2” and “the part between the straight lines L10 and L12 of the outer peripheral region R2”.

### Area Occupancy Proportions S₁₃ and S₂₃

The XY section of the sample mentioned above is observed with an SEM. In the SEM image, the composite bulk member 20B, the central region R1, the outer peripheral region R2 are already identified.

First, the composite bulk member 20B is distinguished into the conductive fiber 21, the dielectric layer 22, the conductor layer 23, and the filling resin (space 24) by image processing. Then, the area of the conductive fibers 21 and dielectric layer 22, and conductor layer 23 in the outer peripheral region R2 is divided by the area of the outer peripheral region R2 (that is, the total of the parts including the conductive fibers 21, the dielectric layer 22, the conductor layer 23, and the filling resin). Thus, the area occupancy proportion S₂₃ of the outer peripheral region R2 is calculated. Similarly, the area occupancy proportion S₁₃ of the central region R1 is calculated.

The area occupancy proportions S₁₃ and S₂₃ in multiple XY sections are calculated in the same manner as mentioned above, except that the cutting position is sequentially changed to a second position, a third position, and. . . . The multiple XY sections are obtained from the same sample (capacitor 1B). For example, the first position is set to a position that is as high as possible, where the height from the front surface 10a of the substrate 10 is 20% or less of the height Hₘₐₓ. Next, the second position is set to a position that is slightly lower than the first position, and the third position is set to a position that is further lower than the second position. In this manner, multiple different XY sections may be exposed from the same sample.

### Modification Example 3

Modification Example 3 is different from Embodiment 3 in the outer shape of the composite bulk member. This different configuration is the same as the difference between Embodiment 1 and the Modification Example 1. The other configurations are the same as those of Embodiment 1, and are denoted by the same reference symbols as those of the Embodiment 1, and will be omitted from description.

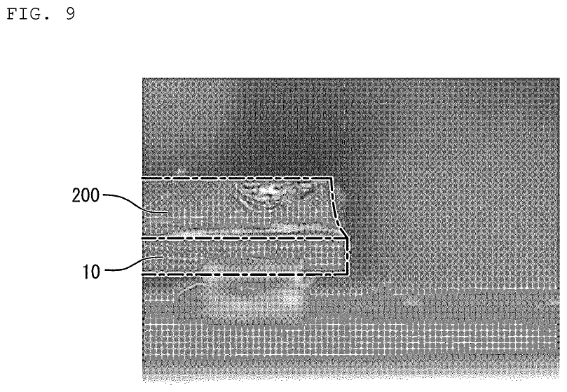

FIG. 8 is a schematic sectional view of a capacitor according to Modification Example 3 of Embodiment 3. FIG. 8 shows a section in an in-plane direction of the substrate 10. An example of a section of the whole capacitor according to Modification Example 3 in an in-plane direction of the substrate 10 is shown in FIG. 6. FIG. 8 corresponds to FIG. 7, and corresponds to an enlarged view of the part D in FIG. 6. An example of a section of the capacitor according to Modification Example 3 in the thickness direction of the substrate 10 is shown in FIGS. 4 and 5. FIG. 8 corresponds to the II-II section of FIG. 5.

As in Modification Examples 1 and 2, in the capacitor 1C according to Modification Example 3, conductive fibers 21 are inclined with respect to the Z direction or bent in the X direction in the outer peripheral region R2 of the XZ section. Thus, the space 24 present in the outer peripheral region R2 is covered with the conductive fibers 21 and reduced. Thus, the outer peripheral region R2 includes a part where the total area occupancy proportion S₂₃ of the conductive fibers 21, dielectric layer 22, and the conductor layer 23 is higher than the total area occupancy proportion S₁₃ of the conductive fibers 21, the dielectric layer 22, and the conductor layer 23 in the central region R1.

While the six embodiments of the present disclosure have been described in detail above, the present disclosure is not limited thereto. For example, any two or more of the respective features of the embodiments describe above may be combined.

In the composite bulk members 20 and 20A according to the embodiments mentioned above, the conductive fibers 21 are directly joined to the substrate 10, but the joint is not limited thereto. The conductive fibers 21 may be joined to the substrate 10, with an adhesive layer with conductivity interposed therebetween. The conductive fibers 21 may be bonded to the surface of the adhesive layer, or may be bonded to the adhesive layer by inserting ends of the conductive fibers 21 into the adhesive layer. The adhesive layer with conductivity is typically formed from a metal material.

In the composite bulk member 20A according to the embodiments described above, the conductive fibers 21 in the outer peripheral regions R2 have contact with each other, with the dielectric layer 22 interposed therebetween or without the dielectric layer 22 interposed therebetween, but the conductive fibers 21 are not limited thereto. The plurality of conductive fibers 21 in the outer peripheral region R2 may be isolated from each other.

In the XY sections of the capacitors 1 and 1B according to the embodiments described above, the outer shapes of the substrates 10 and composite bulk members 20 and 20B are quadrangular, but the outer shapes are not limited thereto. The outer shapes of the substrates 10 and composite bulk members 20 and 20B in the XY sections may be a circle, an ellipse, or a polygon other than a quadrangle.

In the capacitors A and 1A according to the embodiments described above, the conductive fibers 21 and/or the composite bulk members 20 and 20A may be present on the surface (side surface) connecting the surface 10a and the back surface 10b on the substrate 10.

In the embodiment described above, the carbon nanotubes (CNTs) have been exemplified as the conductive fiber 21 in the step (b) or (a′), but the conductive fibers 21 are not limited thereto. The conductive fibers 21 may be conductive fibers other than CNTs.

In the embodiment described above, the forest is provided on the substrate 10 in the step (b) or (a′), but the step is not limited thereto. The forest may be provided on another synthetic substrate, and then transferred to the substrate 10. In this case, the step (c) or (b′) and the subsequent steps may be performed after the transfer. On the substrate 10, an adhesive layer may be provided.

In the embodiment described above, some of the conductive fibers 21 are inclined by agglomeration in the step (b′), but the inclination is not limited thereto. Some of the conductive fibers 21 may be inclined by pressing the forest from the outside toward the center.

In the embodiment described above, the dielectric layer 22 is formed by the sol-gel method in the step (c), but the method is not limited thereto. The dielectric layer 22 may be formed by a vapor phase film formation method (typically, a sputtering method). In this case, the solvent used in the step (b) or (a′) is removed, and then, step (c) is performed. The dielectric layer 22 may be formed by a liquid phase film formation method (typically, a plating method) other than the sol-gel method. When the dielectric layer 22 is made of a metal oxide, a method of plating in combination with a surface oxidation treatment may be used.

### EXAMPLES

The present disclosure will be more specifically described with reference to the following manufacturing example, but the present disclosure is not limited thereto.

### Manufacturing Example 1

Capacitors including composite bulk members according to Modification Examples 1, 2 and 3 were manufactured.

### Preparation of Forest

A catalyst was applied onto the surface of a Si substrate 10, and VACNTs were allowed to grow to obtain a forest 200.

### (2) Inclination of VACNTs

The substrate 10 provided with the forest 200 was immersed in a raw material solution containing sodium dodecyl sulfate, ammonia, and ethanol. The immersion was performed in the following manner. First, the substrate 10 provided with the forest 200 was put into the raw material liquid with a liquid temperature of room temperature (23° C.±3° C.) such that the angle formed by the substrate 10 and the liquid level of the raw material liquid was approximately 90 degrees. The putting speed was set to 5 mm/sec. Thereafter, the substrate 10 was pulled up and dried.

The substrate 10 provided with the forest 200 subjected to the immersion in the raw material solution and the drying was observed with an electron microscope. FIG. 9 shows an image of a part of the substrate 10 with the forest 200. From FIG. 9, it has been confirmed that the CNTs at the edge of the forest 200 were inclined toward the center. In FIG. 9, dot-dash lines indicating the outer edge of the forest 200 and substrate 10 are attached for the sake of convenience.

### (3) Formation of Dielectric Layer

The dielectric layer 22 was formed on the forest 200. Specifically, the VACNTs on the substrate 10 were immersed in a raw material mixed solution obtained by mixing 3-aminopropyltriethoxysilane and ethanol, and kept while stirring at 300 rpm for 1.5 hours at 25° C., and then, the substrate 10 was pulled up. Finally, drying was performed to form a dielectric layer 22 (SiO₂) covering the surface of the plurality of CNTs (conductive fibers 21) on the substrate 10.

### (4) Formation of Conductor Layer

Subsequently, the substrate 10 was immersed in a dispersion liquid containing PEDOT (polyethylene dioxythiophene) and PSS (polystyrene sulfonic acid) to form a conductor layer 23 (composite of PEDOT/PSS) on the dielectric layer 22. In this manner, the capacitors were obtained.

The space present in each of the composite bulk members of the obtained capacitors was filled with a resin, and then, the substrate 10 was viewed from the Z direction to determine the center C of the substrate 10. Then, an XZ section including the center C was exposed by polishing. The obtained section was observed with an SEM. From the SEM image, the maximum height Hₘₐₓ of the CNTs was calculated to be 105 μm. The average length of the fiber-shaped conductive members can be understood to be 50 μm or more.

In the same SEM image, the area occupancy proportions S₁₁ and S₂₁ and the area occupancy proportions S₁₂ and S₂₂ in the section in the thickness direction were calculated as mentioned above, with the region up to about 200 μm from the outer edge of the composite bulk member considered as the outer peripheral region R2 and the other region considered as the central region R1. In at least one section in the thickness direction, the area occupancy proportion S₂₂ satisfied the relationship of S₂₂/S₂₂≥1.36. In addition, in any of sections in the thickness direction, the both outer peripheral regions R2 on one side and the other side can be understood to include a part where the area occupancy proportion S₂₂ was higher than the area occupancy proportion S₁₂ of the central region R1. In addition, in any of sections in the thickness direction, the both outer peripheral regions R2 on one side and the other side can be understood to include a part where the area occupancy proportion S₂₁ was higher than the area occupancy proportion S₁₁ of the central region R1.

With the use of a structure from which parts of multiple sections in the thickness direction were exposed, the area occupancy proportions S₁₃ and S₂₃ of CNTs in the XY section were calculated as mentioned above. In at least one section in the in-plane direction, the area occupancy proportion S₂₃ satisfied the relationship of S₂₃/S₁₃≥1.53. In addition, also in any section in the in-plane direction, the outer peripheral region R2 can be understood to include a part where the area occupancy proportion S₂₃ is higher than the area occupancy proportion S₁₃ of the central region R1.

The average number density N₂ of the conductive fibers 21 in the outer peripheral region R2, calculated from the section in the in-plane direction was 5.28×10⁹ fibers/cm², and the average number density N₂ of the conductive fibers 21 in the central region R1 was 2.36×10⁹ fibers/cm² (ratio N₂/N₁=2.24). The maximum sectional dimension of the CNTs was 33 nm. The thickness of the dielectric layer 22 was 51 nm. The thickness of the conductor layer 23 was 15 nm.

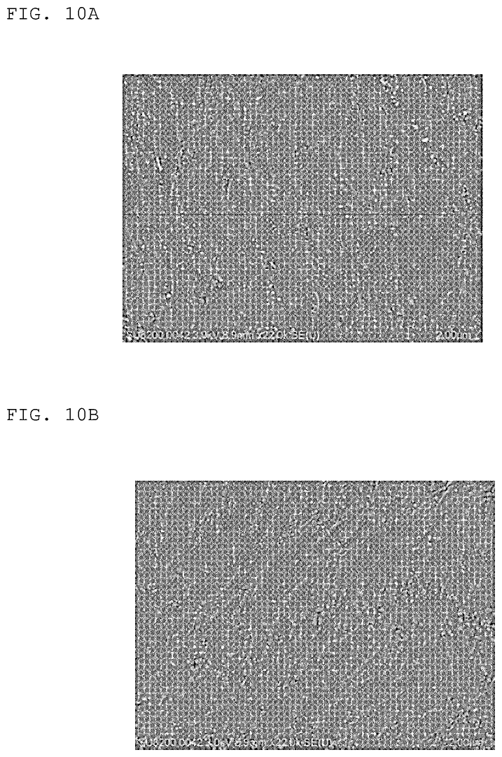

FIG. 10A is an SEM image obtained by photographing a part of the outer peripheral region in the polished XZ section of the composite bulk member obtained according to Manufacturing Example 1. FIG. 10B is an SEM image obtained by photographing a part of the central region in the polished XZ section of the composite bulk member obtained according to Manufacturing Example 1. In FIG. 10A and 10B, parts that appear whitish in linear shapes are the conductive fibers 21 covered with the dielectric layer 22 and the conductor layer 23, and a black part is the filling resin corresponding to the space 24.

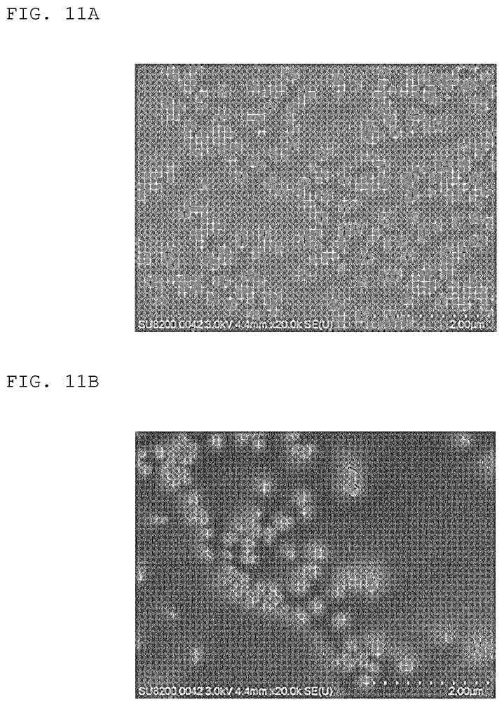

FIG. 11A is an SEM image obtained by photographing a part of the outer peripheral region in the polished XY section of the composite bulk member obtained according to Manufacturing Example 1. FIG. 11B is an SEM image obtained by photographing a part of the central region in the polished XY section of the composite bulk member obtained according to Manufacturing Example 1. In FIG. 11A and 11B, parts that appear whitish in circular shapes are the conductive fibers 21 covered with the dielectric layer 22 and the conductor layer 23, and a black part is the filling resin corresponding to the space 24.

The capacitor according to the present disclosure can be used in any appropriate application, and particularly, can be suitably used in an application that requires high mechanical strength for the composite bulk member.

The following are various configurations of the present disclosure.

<1> A capacitor including: a substrate with conductivity; a plurality of fiber-shaped conductive members disposed on the substrate and electrically connected to the substrate; a dielectric layer that covers the surface of the fiber-shaped conductive members; and a conductor layer that covers the surface of the dielectric layer, wherein the plurality of fiber-shaped conductive members, the dielectric layer, the conductor layer, a space formed among the plurality of fiber-shaped conductive members covered with the dielectric layer and the conductor layer constitute a composite bulk member, in one section in the thickness direction of the substrate, the fiber-shaped conductive member has a maximum height Hₘₐₓ, the composite bulk member has outer peripheral regions on one side and the other side that each occupy a region up to twice the maximum height Hₘₐₓ from an outer edge of the composite bulk member, and a central region sandwiched between the outer peripheral regions on one side and the other side, and the outer peripheral region on at least one of one side and the other side includes a part where the total area occupancy proportion S₁₁ of the fiber-shaped conductive members and the dielectric layer is higher than the total area occupancy proportion S₁₁ of the fiber-shaped conductive members and the dielectric layer in the central region.

<2> The capacitor according to <1>, wherein in one section in the thickness direction of the substrate, both the outer peripheral regions on one side and the other side include a part where the area occupancy proportion S₂₁ is higher than the area occupancy proportion S₁₁.

<3> The capacitor according to <1> or <2>, wherein in each of multiple sections in the thickness direction of the substrate, the outer peripheral region on at least one of one side and the other side includes a part where the area occupancy proportion S₂₁ is higher than the area occupancy proportion S₁₁.

<4> A capacitor including: a substrate with conductivity; a plurality of fiber-shaped conductive members disposed on the substrate and electrically connected to the substrate; a dielectric layer that covers the surface of the fiber-shaped conductive members; and a conductor layer that covers the surface of the dielectric layer, wherein the plurality of fiber-shaped conductive members, the dielectric layer, the conductor layer, a space formed among the plurality of fiber-shaped conductive members covered with the dielectric layer and the conductor layer constitute a composite bulk member, in one section in the thickness direction of the substrate, the fiber-shaped conductive member has a maximum height Hₘₐₓ, the composite bulk member has outer peripheral regions on one side and the other side that each occupy a region up to twice the maximum height Hₘₐₓ from an outer edge of the composite bulk member, and a central region sandwiched between the outer peripheral regions on one side and the other side, and the outer peripheral region on at least one of one side and the other side includes a part where the total area occupancy proportion S₂₂ of the fiber-shaped conductive members, the dielectric layer, and the conductor layer is higher than the total area occupancy proportion S₁₂ of the fiber-shaped conductive members, the dielectric layer, and the conductor layer in the central region.

<5> The capacitor according to <4>, wherein in one section in the thickness direction of the substrate, both the outer peripheral regions on one side and the other side include a part where the area occupancy proportion S₂₂ is higher than the area occupancy proportion S₁₂.

<6> The capacitor according to <4> or <5>, wherein in each of multiple sections in the thickness direction of the substrate, the outer peripheral region on at least one of one side and the other side includes a part where the area occupancy proportion S₂₂ is higher than the area occupancy proportion S₁₂.

<7> A capacitor including: a substrate with conductivity; a plurality of fiber-shaped conductive members disposed on the substrate and electrically connected to the substrate; a dielectric layer that covers the surface of the fiber-shaped conductive members; and a conductor layer that covers the surface of the dielectric layer, wherein the plurality of fiber-shaped conductive members, the dielectric layer, the conductor layer, a space formed among the plurality of fiber-shaped conductive members covered with the dielectric layer and the conductor layer constitute a composite bulk member, in one section in the thickness direction of the substrate, the fiber-shaped conductive member has a maximum height Hₘₐₓ, and in one section in parallel with an in-plane direction of the substrate, the composite bulk member has an outer peripheral region that occupies a region up to twice the maximum height Hₘₐₓ from an outer edge of the composite bulk member, and a central region surrounded by the outer peripheral region, and the outer peripheral region includes a part where the total area occupancy proportion S₂₃ of the fiber-shaped conductive members, the dielectric layer, and the conductor layer is higher than the total area occupancy proportion S₁₃ of the fiber-shaped conductive members, the dielectric layer, and the conductor layer in the central region.

<8> The capacitor according to <7>, wherein in one section in parallel with the in-plane direction of the substrate, parts of the outer peripheral region on both one side and the other side with the central region interposed therebetween include a part where the area occupancy proportion S₂₃ is higher than the area occupancy proportion S₁₃.

<9> The capacitor according to <7> or <8>, wherein in each of multiple sections in parallel with the in-plane direction of the substrate, the outer peripheral region includes a part where the area occupancy proportion S₂₃ is higher than the area occupancy proportion S₁₃.

<10> The capacitor according to any one of <1> to <9>, wherein the dielectric layer has a thickness of 10 nm or more.

<11> The capacitor according to any one of <1> to <10>, wherein the plurality of fiber-shaped conductive members in the outer peripheral region has an average number density N₂ of 10⁸ fibers/cm² or more.

<12> The capacitor according to any one of <1> to <11>, wherein the plurality of fiber-shaped conductive members has an average length of 50 μm or more.

<13> The capacitor according to any one of <1> to <12>, wherein the ratio N₂/N₁ of the average number density N₂ of the plurality of fiber-shaped conductive members in the outer peripheral region to the average number density N₁ Of the plurality of fiber-shaped conductive members in the central region is 2 or more.

<14> The capacitor according to any one of <1> to <13>, wherein the fiber-shaped conductive members are carbon nanotubes.

### DESCRIPTION OF REFERENCE SYMBOLS

1, 1A, 1B, 1C: Capacitor
10: Substrate
10a: Surface
10b: Back surface
20, 20A, 20B: Composite bulk member
21: Fiber-shaped conductive member (conductive fiber)
22: Dielectric layer
22a: Dielectric part
23: Conductor layer
23a: Conductor part
24: Space
200: Forest
C: Center of substrate
AX: Central axis
R1: Central region
R2: Outer peripheral region
L1, L2, L5, L6, L9, L10: Boundary between dielectric layer and dielectric part
L3, L4, L7, L8, L11, L12: Boundary between central region R1 and outer peripheral region R2
T1: Tangent point between first straight line L1 and composite bulk member
T2: Tangent point between second straight line L2 and composite bulk member
P1: Point at distance twice maximum height Hₘₐₓ from tangent point T1 toward central axis AX
P2: Point at distance twice maximum height Hₘₐₓ from tangent point T2 toward central axis AX

1. A capacitor comprising:
a substrate with conductivity;
a plurality of fiber-shaped conductive members on the substrate and electrically connected to the substrate;
a dielectric layer covering a surface of each of the fiber-shaped conductive members; and
a conductor layer covering a surface of the dielectric layer,
wherein
the plurality of fiber-shaped conductive members, the dielectric layer, the conductor layer, a space among the plurality of fiber-shaped conductive members covered with the dielectric layer, and the conductor layer constitute a composite bulk member,
in a first section of the capacitor in a thickness direction of the substrate:
each of the fiber-shaped conductive members has a maximum height Hₘₐₓ,
the composite bulk member has a first outer peripheral region on a first side and a second outer peripheral region on a second side, each of the first outer peripheral region and the second outer peripheral region occupying a region up to twice the maximum height Hₘₐₓ from an outer edge of the composite bulk member, and a central region between the first outer peripheral region on the first side and the second outer peripheral region on the second side, and
at least one of the first outer peripheral region and the second outer peripheral region includes a part where a first total area occupancy proportion of the fiber-shaped conductive members and the dielectric layer is higher than a second total area occupancy proportion of the fiber-shaped conductive members and the dielectric layer in the central region.

2. The capacitor according to claim 1, wherein in the first section in the thickness direction of the substrate, both the first outer peripheral region and the second outer peripheral region include the part where the first total area occupancy proportion is higher than the second total area occupancy proportion.

3. The capacitor according to claim 1, wherein in each of multiple sections in the thickness direction of the substrate, at least one of the first outer peripheral region and the second outer peripheral region includes the part where the first total area occupancy proportion is higher than the second total area occupancy proportion.

4. The capacitor according to claim 1, wherein the dielectric layer has a thickness of 10 nm or more.

5. The capacitor according to claim 1, wherein the plurality of fiber-shaped conductive members in the first outer peripheral region or the second outer peripheral region have an average number density of 108 fibers/cm² or more.

6. The capacitor according to claim 1, wherein the plurality of fiber-shaped conductive members have an average length of 50 μm or more.

7. The capacitor according to claim 1, wherein a ratio N₂/N₁ of an average number density N₂ of the plurality of fiber-shaped conductive members in one or both of the first outer peripheral region and the second outer peripheral region to an average number density N₁ of the plurality of fiber-shaped conductive members in the central region is 2 or more.

8. The capacitor according to claim 1, wherein the fiber-shaped conductive members are carbon nanotubes.

9. A capacitor comprising:
a substrate with conductivity;
a plurality of fiber-shaped conductive members on the substrate and electrically connected to the substrate;
a dielectric layer covering a surface of the fiber-shaped conductive members; and
a conductor layer covering a surface of the dielectric layer,
wherein
the plurality of fiber-shaped conductive members, the dielectric layer, the conductor layer, a space among the plurality of fiber-shaped conductive members covered with the dielectric layer, and the conductor layer constitute a composite bulk member,
in a first section of the capacitor in the thickness direction of the substrate:
each of the fiber-shaped conductive members has a maximum height Hₘₐₓ,
the composite bulk member has a first outer peripheral region on a first side and a second outer peripheral region on a second side, each of the first outer peripheral region and the second outer peripheral region occupying a region up to twice the maximum height Hₘₐₓ from an outer edge of the composite bulk member, and a central region between the first outer peripheral region on the first side and the second outer peripheral region on the second side, and
at least one of the first outer peripheral region and the second outer peripheral region includes a part where a first total area occupancy proportion of the fiber-shaped conductive members, the dielectric layer, and the conductor layer is higher than a second total area occupancy proportion of the fiber-shaped conductive members, the dielectric layer, and the conductor layer in the central region.

10. The capacitor according to claim 9, wherein in the first section in the thickness direction of the substrate, both the first outer peripheral region and the second outer peripheral region include the part where the first total area occupancy proportion is higher than the second total area occupancy proportion.

11. The capacitor according to claim 9, wherein in each of multiple sections in the thickness direction of the substrate, at least one of the first outer peripheral region and the second outer peripheral region includes the part where the first total area occupancy proportion is higher than the second total area occupancy proportion.

12. A capacitor comprising:
a substrate with conductivity;
a plurality of fiber-shaped conductive members on the substrate and electrically connected to the substrate;
a dielectric layer covering a surface of the fiber-shaped conductive members; and
a conductor layer covering a surface of the dielectric layer,
wherein
the plurality of fiber-shaped conductive members, the dielectric layer, the conductor layer, a space among the plurality of fiber-shaped conductive members covered with the dielectric layer, and the conductor layer constitute a composite bulk member,
in a first section of the capacitor in a thickness direction of the substrate each of the fiber-shaped conductive members has a maximum height Hₘₐₓ, and
in a second section of the capacitor in parallel with an in-plane direction of the substrate:
the composite bulk member has an outer peripheral region that occupies a region up to twice the maximum height Hₘₐₓ from an outer edge of the composite bulk member, and a central region surrounded by the outer peripheral region, and
the outer peripheral region includes a part where a first total area occupancy proportion of the fiber-shaped conductive members, the dielectric layer, and the conductor layer is higher than a second total area occupancy proportion of the fiber-shaped conductive members, the dielectric layer, and the conductor layer in the central region.

13. The capacitor according to claim 12, wherein in the second section in parallel with the in-plane direction of the substrate, parts of the outer peripheral region on opposed sides of the central region include the part where the first total area occupancy proportion is higher than the second total area occupancy proportion.

14. The capacitor according to claim 12, wherein in each of multiple sections of the capacitor in parallel with the in-plane direction of the substrate, the outer peripheral region includes the part where the first total area occupancy proportion is higher than the second total area occupancy proportion.

15. The capacitor according to claim 12, wherein the dielectric layer has a thickness of 10 nm or more.

16. The capacitor according to claim 12, wherein the plurality of fiber-shaped conductive members in the outer peripheral region have an average number density of 10⁸ fibers/cm² or more.

17. The capacitor according to claim 12, wherein the plurality of fiber-shaped conductive members have an average length of 50 μm or more.

18. The capacitor according to claim 12, wherein a ratio N₂/N₁ of an average number density N₂ of the plurality of fiber-shaped conductive members in the outer peripheral region to an average number density N₁ of the plurality of fiber-shaped conductive members in the central region is 2 or more.

19. The capacitor according to claim 12, wherein the fiber-shaped conductive members are carbon nanotubes.
